(19) United States
(12) Patent Application Publication
(10) Pub. No.: US 2024/0074155 A1
(43) Pub. Date: Feb. 29, 2024

(54) SEMICONDUCTOR DEVICE

(71) Applicant: Samsung Electronics Co., Ltd., Suwon-si (KR)

(72) Inventors: Taehyuk Kim, Suwon-si (KR); Taegyu Kang, Suwon-si (KR); Seokho Shin, Suwon-si (KR); Kiseok Lee, Suwon-si (KR); Sangho Lee, Suwon-si (KR); Keunnam Kim, Suwon-si (KR); Seokhan Park, Suwon-si (KR); Joongchan Shin, Suwon-si (KR); Moonyoung Jeong, Suwon-si (KR); Eunju Cho, Suwon-si (KR)

(21) Appl. No.: 18/236,143

(22) Filed: Aug. 21, 2023

(30) Foreign Application Priority Data
Aug. 24, 2022 (KR) 10-2022-0106351

(51) Int. Cl. H10B 12/00

(52) U.S. Cl. CPC H10B 12/482; H10B 12/315; H10B 12/488

(57) ABSTRACT

A semiconductor device includes a substrate, a bit line extending on the substrate in a first direction, first and second active patterns on the bit line, a back-gate electrode between the first and second active patterns and extending across the bit line and in a second direction that is perpendicular to the first direction, a first word line extending in the second direction at one side of the first active pattern, a second word line extending in the second direction at the other side of the second active pattern, and a contact pattern connected to each of the first and second active patterns, wherein the contact pattern sequentially includes an epitaxial growth layer, a doped polysilicon layer, and a silicide layer.

### CROSS-REFERENCE TO RELATED APPLICATION

This application is based on and claims priority under 35 U.S.C. § 119 to Korean Patent Application No. 10-2022-0106351, filed on Aug. 24, 2022, in the Korean Intellectual Property Office, the disclosure of which is incorporated by reference herein in its entirety.

### BACKGROUND

The inventive concept relates to a semiconductor device, and more particularly, to a semiconductor device including a vertical-channel transistor.

To satisfy excellent performance and economic feasibility, it is demanded to increase a degree of integration of a semiconductor device. In particular, a degree of integration of a memory device is a significant factor in determining the economic feasibility of a product. A degree of integration of a two-dimensional memory device is mostly determined by an area occupied by a unit memory cell and thus largely depends on a level of a fine pattern forming technique. However, expensive instruments are needed to form a fine pattern, and an area of a chip die is limited, and thus, a degree of integration of a two-dimensional memory device has been increasing but is still limited.

### SUMMARY

The inventive concept provides a semiconductor device of which the degree of integration and the electrical characteristics are improved, and which includes a vertical-channel transistor.

The problems to be solved by the technical idea of the inventive concept are not limited to the problem mentioned above, and the other problems, which are not mentioned, could be clearly understood by those of ordinary skill in the art from the description below.

According to an aspect of the inventive concept, a semiconductor device includes a substrate, a first bit line extending on the substrate in a first direction, first and second active patterns on the first bit line, a back-gate electrode between the first and second active patterns and extending across the first bit line in a second direction that is perpendicular to the first direction, a first word line extending in the second direction, wherein the first active pattern is disposed between the first word line and the back-gate electrode, a second word line extending in the second direction, wherein the second active pattern is disposed between the second word line and the back-gate electrode, and a contact pattern connected to each of the first and second active patterns. The contact pattern includes an epitaxial growth layer, a doped polysilicon layer, and a silicide layer that are stacked on each other in a vertical direction perpendicular to an upper surface of the substrate.

According to another aspect of the inventive concept, a semiconductor device includes a substrate, a bit line extending on the substrate in a first direction, first and second active patterns on the bit line, a back-gate electrode between the first and second active patterns and extending across the bit line in a second direction that is perpendicular to the first direction, a first word line extending in the second direction at a first side of the first active pattern, a second word line extending in the second direction at a second side of the second active pattern, and a contact pattern connected to each of the first and second active patterns. The contact pattern includes an undoped epitaxial growth layer, a doped epitaxial growth layer, and a silicide layer that are stacked on each other in a vertical direction perpendicular to an upper surface of the substrate.

According to another aspect of the inventive concept, a semiconductor device includes a substrate, a first bit line extending on the substrate in a first direction, a second bit line adjacent to the first bit line, a gap structure disposed in a space between the first and second bit lines and extending in the first direction, first and second active patterns alternately arranged on the first bit line in the first direction, a back-gate electrode between the first and second active patterns and extending across the first bit line in a second direction that is perpendicular to the first direction, a first word line neighboring to the first active pattern and extending in the second direction, a second word line neighboring to the second active pattern and extending in the second direction, a gate insulating pattern between the first and second active patterns and the first and second word lines, a back-gate insulating pattern between the back-gate electrode and each of the first and second active patterns, a contact pattern connected to each of the first and second active patterns, a landing pad on the contact pattern, and a data storage pattern connected to the landing pad. The contact pattern includes an undoped epitaxial growth layer, a doped epitaxial growth layer on the undoped epitaxial growth layer and having a gradually increasing doping concentration, a doped polysilicon layer disposed on the doped epitaxial growth layer and doped at a higher concentration than a concentration of the doped epitaxial growth layer, and a metal silicide layer on the doped polysilicon layer.

### BRIEF DESCRIPTION OF THE DRAWINGS

Embodiments of the inventive concept will be more clearly understood from the following detailed description taken in conjunction with the accompanying drawings in which:

FIG. 1 is a perspective view illustrating a part of a semiconductor device according to an embodiment;

FIG. 2 is a layout illustrating a semiconductor device according to an embodiment;

FIG. 3 illustrates cross-sectional views of the semiconductor device of FIG. 2, taken along lines A-A′ and B-B′;

FIG. 4 is a magnified cross-sectional view of a part IV of the semiconductor device of FIG. 3;

FIGS. 5 and 6 are cross-sectional views illustrating semiconductor devices according to other embodiments; and

FIGS. 7 to 30 are cross-sectional views illustrating, in a process order, a method of manufacturing a semiconductor device, according to an embodiment.

### DETAILED DESCRIPTION OF THE EMBODIMENTS

Hereinafter, embodiments of the inventive concept are described in detail with reference to the accompanying drawings.

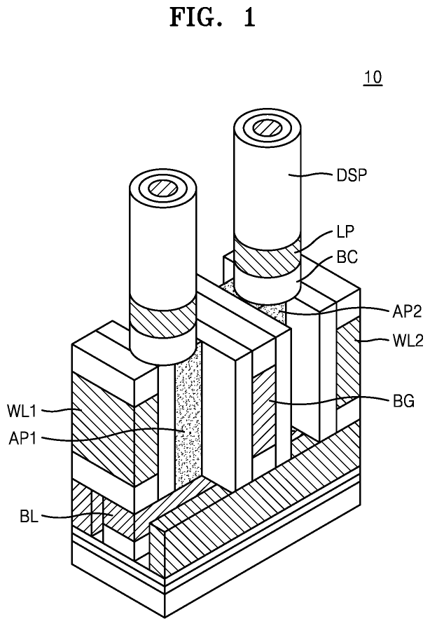

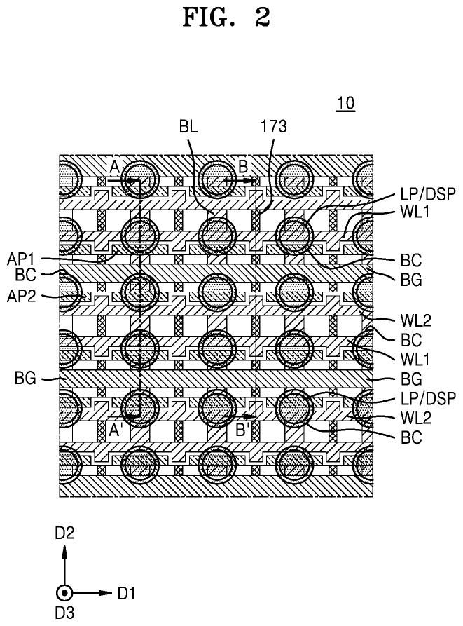

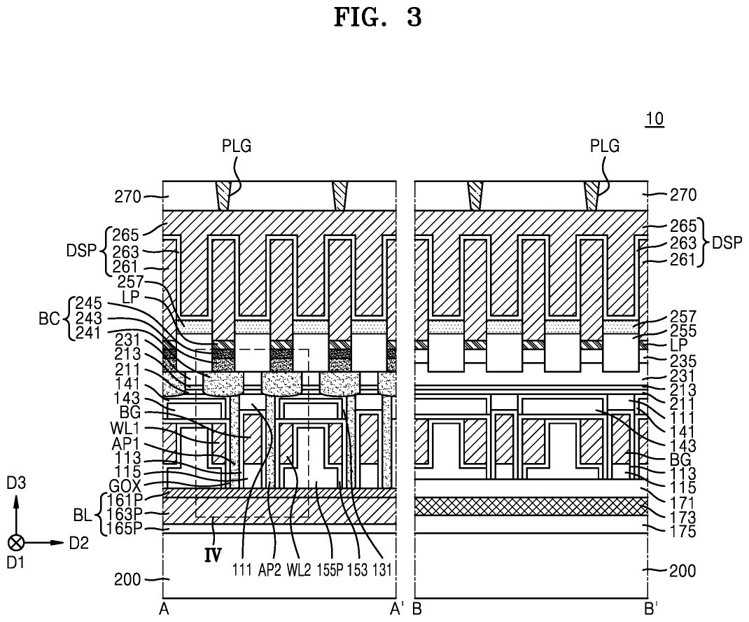

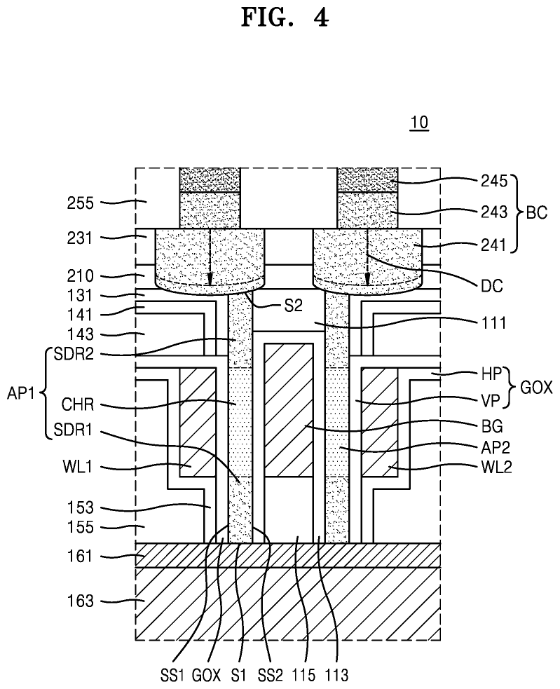

FIG. 1 is a perspective view illustrating a part of a semiconductor device 10 according to an embodiment, FIG. 2 is a layout illustrating the semiconductor device 10 according to an embodiment, FIG. 3 illustrates cross-sectional views of the semiconductor device 10 of FIG. 2, taken along lines A-A′ and B-B′, and FIG. 4 is a magnified cross-sectional view of a part IV of the semiconductor device 10 of FIG. 3.

However, for convenience of description, FIG. 1 shows only some components included in the semiconductor device 10.

Referring to FIGS. 1 to 4, the semiconductor device 10 according to an embodiment may include memory cells each including one vertical-channel transistor (VCT) and one capacitor.

Bit lines BL may be on a substrate 200 to be separated from each other in a first direction D1. The bit lines BL may be separated from each other in the first direction D1 and extend in a second direction D2 intersecting with the first direction D1. The first and second directions D1 and D2 may be parallel to an upper surface of the substrate 200.

The substrate 200 may include or may be formed of a material (e.g., silicon (Si) or germanium (Ge)) having a semiconductor characteristic, an insulating material (e.g., glass or quartz), or a semiconductor or a conductor covered by the insulating material.

Each of the bit lines BL may include a polysilicon pattern 161P, a metal pattern 163P, and a hardmask pattern 165P, which are sequentially stacked. Herein, the hardmask pattern 165P in each of the bit lines BL may be in contact with the substrate 200. The metal pattern 163P may include or may be formed of conductive metal nitride (e.g., titanium nitride (TiN) or tantalum nitride (TaN)) or a metal (e.g., tungsten (W), titanium (Ti), or tantalum (Ta)). Alternatively, the metal pattern 163P may include or may be formed of metal silicide, such as titanium silicide (TiSi), cobalt silicide (CoSi), and nickel silicide (NiSi). The hardmask pattern 165P may include or may be formed of an insulating material, such as silicon nitride and silicon oxynitride. The term “contact,” as used herein, refers to a direct connection (i.e., touching) unless the context indicates otherwise.

In some embodiments, the semiconductor device 10 may include gap structures 173 between the bit lines BL. Each of the gap structures 173 may be surrounded by line insulating layers 171 and 175.

The gap structures 173 may extend in parallel to each other in the second direction D2. The gap structures 173 may be provided between the line insulating layers 171 and 175, and upper surfaces of the gap structures 173 may be positioned at a lower level than upper surfaces of the bit lines BL.

In some embodiments, the gap structures 173 may include a conductive material and include air gaps or voids therein. In other embodiments, the air gaps may be surrounded by the gap structures 173 and the line insulating layers 171 and 175. The gap structures 173 may reduce coupling noise between adjacent bit lines BL. For example, the gap structures 173 may include shield lines made of a conductive material. The phrase “air gap” will be understood to include gaps (e.g., pockets) of air or gases other than air, such as other atmospheric gases and chamber gases that may be present during manufacturing. An “air gap” may also constitute a space having no or substantially no gas or other material therein.

First and second active patterns AP1 and AP2 may be on each of the bit lines BL alternately in the second direction D2. The first active patterns AP1 may be separated by a certain distance from each other in the first direction D1, and the second active patterns AP2 may be separated by a certain distance from each other in the first direction D1. In other words, the first and second active patterns AP1 and AP2 may be two-dimensionally arranged in the first direction D1 and the second direction D2 intersecting with each other.

In some embodiments, the first and second active patterns AP1 and AP2 may include or may be formed of a monocrystalline semiconductor material. For example, the first and second active patterns AP1 and AP2 may include or may be formed of monocrystalline S1.

Each of the first and second active patterns AP1 and AP2 may have a length in the first direction D1, have a width in the second direction D2, and have a height in a third direction D3 that is perpendicular to the upper surface of the substrate 200. Each of the first and second active patterns AP1 and AP2 may have a substantially uniform width. That is, each of the first and second active patterns AP1 and AP2 may have substantially the same width on first and second surfaces S1 and S2. Terms such as “same,” “equal,” “planar,” “uniform,” or “coplanar,” as used herein encompass near identicality including variations that may occur, for example, due to manufacturing processes. The term “substantially” may be used herein to emphasize this meaning, unless the context or other statements indicate otherwise.

Each of the first and second active patterns AP1 and AP2 may have the first surface S1 and the second surface S2 facing each other in a direction that is perpendicular to the first and second directions D1 and D2. For example, the first surfaces S1 of the first and second active patterns AP1 and AP2 may be in contact with the polysilicon pattern 161P of a bit line BL or with the metal pattern 163P if the polysilicon pattern 161P is omitted.

Each of the first and second active patterns AP1 and AP2 may have a first side surface SS1 and a second side surface SS2 facing each other in the second direction D2. The first side surface SS1 of the first active pattern AP1 may be adjacent to a first word line WL1, and the second side surface SS2 of the second active pattern AP2 may be adjacent to a second word line WL2.

Each of the first and second active patterns AP1 and AP2 may include a first dopant region SDR1 adjacent to the bit line BL, a second dopant region SDR2 adjacent to a contact pattern BC, and a channel region CHR between the first and second dopant regions SDR1 and SDR2. The first and second dopant regions SDR1 and SDR2 are regions doped with a dopant in each of the first and second active patterns AP1 and AP2, and a dopant concentration in the first and second dopant regions SDR1 and SDR2 may be greater than a dopant concentration in the channel region CHR. For example, the first dopant region SDR1 may be referred to as a source region, and the second dopant region SDR2 may be referred to as a drain region.

The channel regions CHR of the first and second active patterns AP1 and AP2 may be controlled by first and second word lines WL1 and WL2 and back-gate electrodes BG when the semiconductor device 10 operates. Because the first and second active patterns AP1 and AP2 include or are formed of a monocrystalline semiconductor material, a leakage current characteristic may be improved when the semiconductor device 10 operates.

The back-gate electrodes BG may be on the bit lines BL to be separated by a certain distance from each other in the second direction D2. The back-gate electrodes BG may extend across the bit lines BL and in the first direction D1.

Each of the back-gate electrodes BG may be between the first and second active patterns AP1 and AP2 adjacent to each other in the second direction D2. In other words, the first active pattern AP1 may be at one side of each of the back-gate electrodes BG, and the second active pattern AP2 may be at the other side of each of the back-gate electrodes BG. The back-gate electrodes BG may have a less height than the first and second active patterns AP1 and AP2 in the third direction D3.

The back-gate electrodes BG may include or may be formed of, for example, doped polysilicon, conductive metal nitride (e.g., TiN or TaN), a metal (e.g., W, Ti, or Ta), conductive metal silicide, conductive metal oxide, or a combination thereof.

A negative voltage may be applied to the back-gate electrodes BG when the semiconductor device 10 operates, thereby increasing a threshold voltage of a VCT. That is, degradation of a leakage current characteristic due to a decrease of the threshold voltage according to miniaturization of the VCT may be prevented.

A first insulating pattern 111 may be between first and second active patterns AP1 and AP2 adjacent to each other in the second direction D2. The first insulating pattern 111 may be between second dopant regions SDR2 of the first and second active patterns AP1 and AP2. The first insulating pattern 111 may extend in the first direction D1 to be parallel to the back-gate electrodes BG. A distance between the second surface S2 of each of the first and second active patterns AP1 and AP2 and a back-gate electrode BG may vary depending on a thickness of the first insulating pattern 111. The first insulating pattern 111 may include or may be formed of, for example, a silicon oxide layer, a silicon oxynitride layer, or a silicon nitride layer.

A back-gate insulating pattern 113 may be between each back-gate electrode BG and the first and second active patterns AP1 and AP2 and between the back-gate electrode BG and the first insulating pattern 111. The back-gate insulating pattern 113 may include vertical portions covering opposite side surfaces of the back-gate electrode BG and a horizontal portion connecting the vertical portions. The horizontal portion of the back-gate insulating pattern 113 may be closer to the contact pattern BC than the bit line BL and cover a top surface of the back-gate electrode BG.

The back-gate insulating pattern 113 may include or may be formed of, for example, a silicon oxide layer, a silicon oxynitride layer, a high-k dielectric layer having a higher dielectric constant than the silicon oxide layer, or a combination thereof.

A back-gate capping pattern 115 may be between the bit lines BL and the back-gate electrode BG. The back-gate capping pattern 115 may include or may be formed of an insulating material, and a lower surface of the back-gate capping pattern 115 may be in contact with the polysilicon pattern 161P of each of the bit lines BL. The back-gate capping pattern 115 may be between the vertical portions of the back-gate insulating pattern 113. A thickness of the back-gate capping pattern 115 between the bit lines BL may be different from a thickness of the back-gate capping pattern 115 on the bit lines BL.

The first and second word lines WL1 and WL2 may extend on the bit lines BL in the first direction D1 and may be alternately arranged in the second direction D2.

The first word line WL1 may be at one side of the first active pattern AP1, and the second word line WL2 may be at the other side of the second active pattern AP2. The first and second word lines WL1 and WL2 may be vertically separated from the bit lines BL and contact patterns BC. In other words, the first and second word lines WL1 and WL2 may be between the bit lines BL and the contact patterns BC in a front view.

The first and second word lines WL1 and WL2 may have a width in the second direction D2, and the width of each of the first and second word lines WL1 and WL2 on the bit line BL may be different from the width of each of the first and second word lines WL1 and WL2 on a gap structure 173. Portions of the first word lines WL1 may be respectively between first active patterns AP1 adjacent to each other in the first direction D1, and portions of the second word lines WL2 may be respectively between second active patterns AP2 adjacent to each other in the first direction D1.

The first and second word lines WL1 and WL2 may include or may be formed of, for example, doped polysilicon, a metal, conductive metal nitride, conductive metal silicide, conductive metal oxide, or a combination thereof.

First and second word lines WL1 and WL2 adjacent to each other may have respective side walls facing each other. The first and second word lines WL1 and WL2 may have a less height than the first and second active patterns AP1 and AP2 in the third direction D3. The height of the first and second word lines WL1 and WL2 may be less than or equal to a height of the back-gate electrodes BG in the third direction D3.

Gate insulating patterns GOX may be between the first and second word lines WL1 and WL2 and the first and second active patterns AP1 and AP2, respectively. The gate insulating patterns GOX may extend in the first direction D1 to be parallel to the first and second word lines WL1 and WL2.

The gate insulating pattern GOX may include a silicon oxide layer, a silicon oxynitride layer, a high-k dielectric layer having a higher dielectric constant than the silicon oxide layer, or a combination thereof. The high-k dielectric layer may include metal oxide or metal oxynitride. For example, the high-k dielectric layer usable for the gate insulating pattern GOX may include hafnium oxide (HfO₂), hafnium silicon oxide (HfSiO), hafnium silicon oxynitride (HfSiON), hafnium tantalum oxide (HfTaO), hafnium titanium oxide (HMO), hafnium zirconium oxide (HfZrO), zirconium oxide (ZrO₂), aluminum oxide (Al₂O₃), or a combination thereof but is not limited thereto.

The gate insulating pattern GOX may cover a first side surface of the first active pattern AP1 and a second side surface of the second active pattern AP2. The gate insulating pattern GOX may have a substantially uniform thickness. Each of the gate insulating patterns GOX may include a vertical portion VP adjacent to each of the first and second active patterns AP1 and AP2 and a horizontal portion HP protruding from the vertical portion VP in the first direction D1.

A second insulating pattern 143 may be between the horizontal portion HP of the gate insulating pattern GOX and each of the contact patterns BC. For example, the second insulating pattern 143 may include or may be formed of silicon oxide. First and second etching stop layers 131 and 141 may be disposed between the second insulating pattern 143 and each of the second dopant regions SDR2 of the first and second active patterns AP1 and AP2.

On the gate insulating pattern GOX, the first and second word lines WL1 and WL2 may be separated from each other by a third insulating pattern 155P. The third insulating pattern 155P may extend in the first direction D1 between the first and second word lines WL1 and WL2. A first capping layer 153 may be between the third insulating pattern 155P and each of the first and second word lines WL1 and WL2. The first capping layer 153 may have a substantially uniform thickness.

The contact patterns BC may pass through an interlayer insulating layer 231 and an etching stop layer 210 and may be respectively connected to the first and second active patterns AP1 and AP2. In other words, the contact patterns BC may be connected to the second dopant regions SDR2 of the first and second active patterns AP1 and AP2, respectively. In the contact patterns BC, a lower width may be greater than an upper width. The contact patterns BC adjacent to each other may be separated from each other by isolation insulating patterns 255, respectively. Each of the contact patterns BC may have various shapes, such as a circular shape, an oval shape, a rectangular shape, a square shape, a diamond shape, and a hexagonal shape, in a top view.

In the semiconductor device 10 according to the present embodiment, each of the contact patterns BC may have a stacked structure sequentially including an epitaxial growth layer 241, a doped polysilicon layer 243, and a silicide layer 245.

The epitaxial growth layer 241 may be in contact with a corresponding one of the first and second active patterns AP1 and AP2. The epitaxial growth layer 241 may have a doping concentration DC that gradually varies in the third direction D3 that is perpendicular to the upper surface of the substrate 200. Particularly, the doping concentration DC of the inside of the epitaxial growth layer 241 may gradually decrease away from the doped polysilicon layer 243. In other words, the doping concentration DC of the inside of the epitaxial growth layer 241 may gradually increase away from the substrate 200. In addition, a lower region of the epitaxial growth layer 241 contacting each of the first and second active patterns AP1 and AP2 may be formed as an undoped underlap section.

Due to a doping scheme for the epitaxial growth layer 241, which is to be described below, dopants included in the epitaxial growth layer 241 may be dopants moved from the doped polysilicon layer 243 by a thermal diffusion method. That is, a type of the dopants in the epitaxial growth layer 241 may be the same as a type of the dopants in the doped polysilicon layer 243. The dopant may be an n-type dopant (e.g., phosphorus or arsenic) but is not limited thereto. In addition, the doping concentration DC of the epitaxial growth layer 241 may be about 3×10²⁰/cm³ near the doped polysilicon layer 243, may gradually decrease, and may be about 2.5×10¹⁹/cm³ near the underlap section. However, the doping concentration DC of the epitaxial growth layer 241 is not limited to the numeric values described above. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In addition, the epitaxial growth layer 241 may include or may be formed of a monocrystalline Si epitaxial growth layer or a SiGe epitaxial growth layer but is not limited thereto.

The doped polysilicon layer 243 may be disposed by forming, on the epitaxial growth layer 241, polysilicon doped with an n-type dopant or a p-type dopant at a high concentration. A doping concentration of dopants in the doped polysilicon layer 243 may be sufficiently high so that some of the dopants included in the doped polysilicon layer 243 move to the epitaxial growth layer 241 and dope the epitaxial growth layer 241.

The silicide layer 245 may include or may be formed of metal silicide, e.g., CoSi, NiSi, or TiSi. The silicide layer 245 may be formed by reacting a metal layer react with the doped polysilicon layer 243 to form the silicide layer 245 and then removing a remaining portion of the metal layer, which has not reacted.

By performing an annealing process, some of highly concentrated dopants included in the doped polysilicon layer 243 may move to the epitaxial growth layer 241 by a thermal diffusion method. Accordingly, the epitaxial growth layer 241 may have the doping concentration DC gradually decreasing away from a junction interface with the doped polysilicon layer 243. Therefore, the epitaxial growth layer 241 may be formed to have a certain junction depth that corresponds to a distance between the junction interface and an upper surface of the epitaxial growth layer 124. In some embodiments, the junction depth of the epitaxial growth layer 241 may be a maximum distance between the junction interface and the upper surface of the epitaxial growth layer 124.

Landing pads LP may be on the contact patterns BC, respectively. Particularly, each of the landing pads LP may be disposed to be in contact with the silicide layer 245. Each of the landing pads LP may have various shapes, such as a circular shape, an oval shape, a rectangular shape, a square shape, a diamond shape, and a hexagonal shape, in a top view.

The isolation insulating patterns 255 may be between the landing pads LP, respectively. The landing pads LP may be arranged in a matrix form in the first direction D1 and the second direction D2 in a top view. Upper surfaces of the landing pads LP may be substantially coplanar with upper surfaces of the isolation insulating patterns 255.

The landing pads LP may include or may be formed of doped polysilicon, aluminum (Al), copper (Cu), Ti, Ta, rubidium (Ru), W, molybdenum (Mo), platinum (Pt), nickel (Ni), cobalt (Co), TiN, TaN, tungsten nitride (WN), niobium nitride (NbN), titanium aluminum (TiAl), titanium aluminum nitride (TiAlN), TiSi, titanium silicon nitride (TiSiN), TaSi, tantalum silicon nitride (TaSiN), rubidium titanium nitride (RuTiN), NiSi, CoSi, iridium oxide (IrO), rubidium oxide (RuO), or a combination thereof but is not limited thereto.

Data storage patterns DSP may be on the landing pads LP, respectively. The data storage patterns DSP may be electrically connected to the first and second active patterns AP1 and AP2, respectively. The data storage patterns DSP may be arranged in a matrix form in the first direction D1 and the second direction D2. The data storage patterns DSP may fully or partially overlap the landing pads LP, respectively. The data storage patterns DSP may fully or partially contact upper surfaces of the landing pads LP, respectively.

In some embodiments, each of the data storage patterns DSP may be a capacitor and include storage electrodes 261, a plate electrode 265, and a capacitor dielectric layer 263 between the storage electrodes 261 and the plate electrode 265. In this case, the storage electrode 261 may contact the landing pad LP. The storage electrode 261 may have various shapes, such as a circular shape, an oval shape, a rectangular shape, a square shape, a diamond shape, and a hexagonal shape, in a top view.

Alternatively, each of the data storage patterns DSP may be a variable resistance pattern which may switch to two resistance states by an electrical pulse applied to a memory element. For example, the data storage patterns DSP may include or may be formed of a phase-change material of which a crystal structure changes according to a current amount, such as a perovskite compound, transition metal oxide, a magnetic material, a ferromagnetic material, and an antiferromagnetic material. The present invention is not limited thereto.

An upper insulating layer 270 may be on the data storage patterns DSP, and cell contact plugs PLG may be connected to the plate electrode 265 by passing through the upper insulating layer 270.

Although not shown, peripheral circuit transistors may be in a peripheral circuit region of the substrate 200. In the peripheral circuit region, an active layer may include or may be formed of the same monocrystalline semiconductor material as the first and second active patterns AP1 and AP2. The active layer may have a first surface in contact with the substrate 200 and a second surface that is opposite to the first surface. The first surface of the active layer may be substantially coplanar with the first surfaces S1 of the first and second active patterns AP1 and AP2.

The peripheral circuit transistors may be on the second surface of the active layer. That is, a peripheral gate insulating layer may be on the second surface of the active layer, and a peripheral gate electrode may be on the peripheral gate insulating layer. The peripheral gate electrode may include a peripheral conductive pattern, a peripheral metal pattern, and a peripheral mask pattern.

The semiconductor device 10 according to the technical idea of the inventive concept includes a stacked structure including the doped epitaxial growth layer 241 in each of the contact patterns BC electrically connecting the first and second active patterns AP1 and AP2 to the data storage patterns DSP, in a structure including a VCT. By doing this, a certain junction depth may be ensured between the first and second active patterns AP1 and AP2 and the contact patterns BC. In addition, an undoped underlap section may be in a lower region of the epitaxial growth layer 241, thereby reducing gate induced drain leakage (GIDL).

Ultimately, the semiconductor device 10 according to the technical idea of the inventive concept has an effect of improving a degree of integration and electrical characteristics.

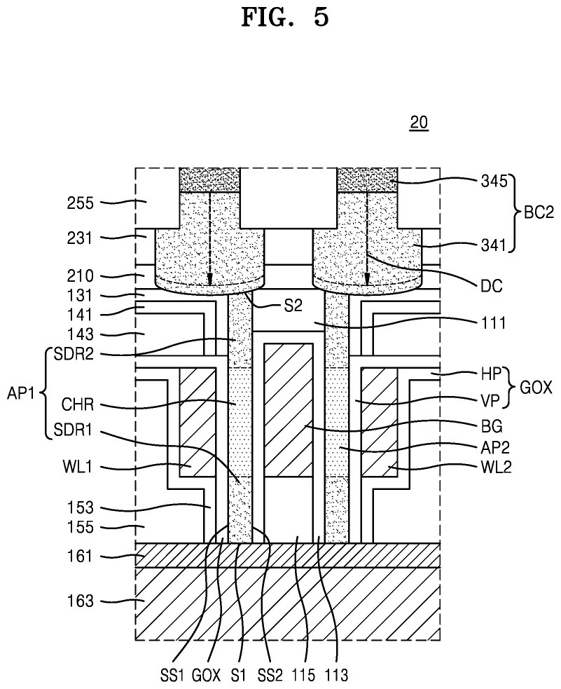

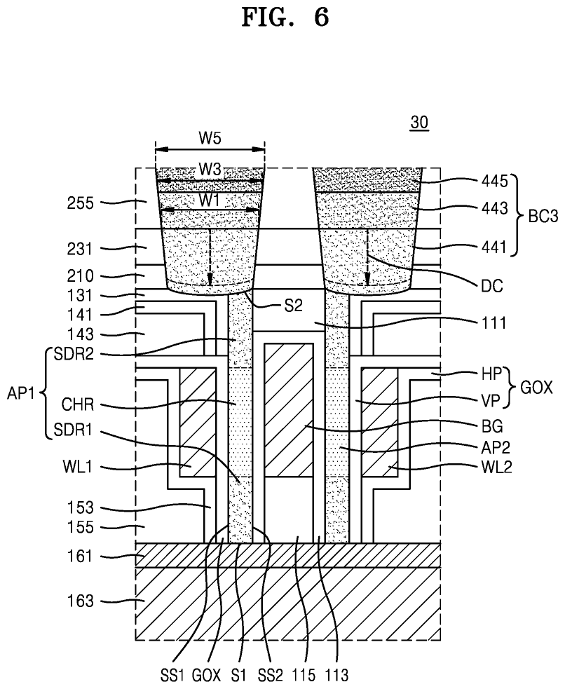

FIGS. 5 and 6 are cross-sectional views illustrating semiconductor devices 20 and 30 according to other embodiments.

Most components constituting the semiconductor devices 20 and 30 to be described below and materials forming the components are substantially the same as or similar to those described with reference to FIGS. 1 to 4. Therefore, for convenience of description, differences from the semiconductor device 10 described above are mainly described.

Referring to FIG. 5, the semiconductor device 20 according to an embodiment may include memory cells each including a VCT.

In the semiconductor device 20 according to the present embodiment, each of contact patterns BC2 may sequentially include an epitaxial growth layer 341 and a silicide layer 345.

The epitaxial growth layer 341 may be in contact with each of the first and second active patterns AP1 and AP2 and formed so that the doping concentration DC gradually varies in the third direction D3. Particularly, the doping concentration DC of the inside of the epitaxial growth layer 341 may be adjusted by a gas phase doping (GPD) process or a plasma assisted doping (PLAD) process. A doping process on the epitaxial growth layer 341 may be performed in-situ in a selective epitaxial growth (SEG) process.

That is, a self-aligned junction may be formed between the first and second active patterns AP1 and AP2 and the contact patterns BC2 by a GPD or PLAD process, and the self-aligned junction may determine a certain junction depth.

The silicide layer 345 may include or may be formed of metal silicide, e.g., CoSi, NiSi, or TiSi. The silicide layer 345 may be formed by reacting a metal layer react with the doped epitaxial growth layer 341 to form the silicide layer 345 and then removing a remaining portion of the metal layer, which has not reacted.

Referring to FIG. 6, the semiconductor device 30 according to an embodiment may include memory cells each including a VCT.

In the semiconductor device 30 according to the present embodiment, each of contact patterns BC3 may sequentially include an epitaxial growth layer 441, a doped polysilicon layer 443, and a silicide layer 445.

The epitaxial growth layer 441 may be in contact with each of the first and second active patterns AP1 and AP2. The epitaxial growth layer may have the doping concentration DC that gradually varies in the third direction D3. The epitaxial growth layer 441 may have a width W1 in the second direction D2.

The doped polysilicon layer 443 may be disposed by forming, on the epitaxial growth layer 441, polysilicon doped with an n-type dopant or a p-type dopant at a high concentration. A width of the doped polysilicon layer 443 in the second direction D2 may be greater than the width W1 of the epitaxial growth layer 441.

The silicide layer 445 may be formed by reacting a metal layer react with the doped polysilicon layer 443 to form the silicide layer 445 and then removing a remaining portion of the metal layer, which has not reacted. A width W5 of the silicide layer 445 in the second direction D2 may be greater than the width W3 of the doped polysilicon layer 443.

That is, the contact patterns BC3 may have a tapered shape having a width gradually decreasing downward.

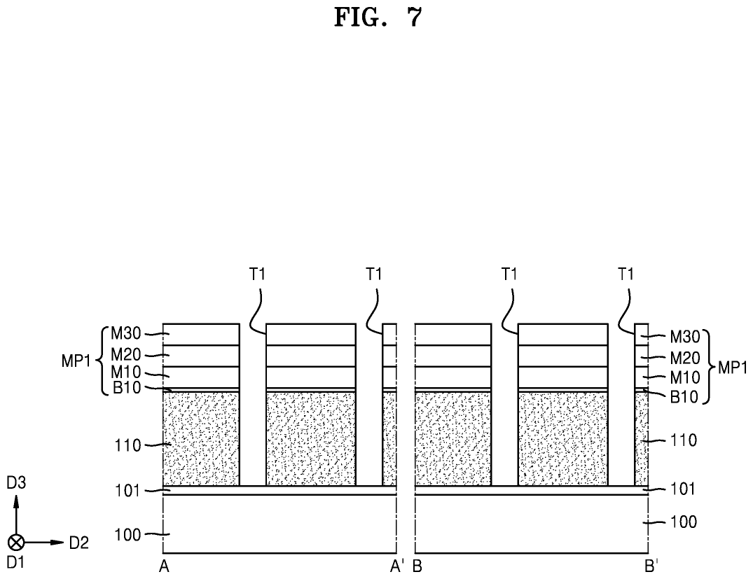

FIGS. 7 to 30 are cross-sectional views illustrating, in a process order, a method of manufacturing a semiconductor device, according to an embodiment.

Particularly, each of FIGS. 7 to 30 shows cross-sections taken along lines A-A′ and B-B′ of FIG. 2.

Referring to FIG. 7, a first substrate 100 including a buried insulating layer 101 and an active layer 110 may be prepared.

The first substrate 100 may be a wafer including Si. Alternatively, the first substrate 100 may be a wafer including a semiconductor element, such as Ge, and a compound semiconductor. The compound semiconductor may include silicon carbide (SiC), gallium arsenide (GaAs), indium arsenide (InAs), or indium phosphide (InP). In addition, the first substrate 100 may have a silicon on insulator (SOI) structure.

The buried insulating layer 101 may include or may be formed of, for example, buried oxide. Alternatively, the buried insulating layer 101 may be an insulating layer formed by chemical vapor deposition (CVD). The buried insulating layer 101 may include or may be formed of, for example, silicon oxide, silicon nitride, silicon oxynitride, and/or a low-k dielectric material.

The active layer 110 may include or may be formed of a monocrystalline semiconductor material. The active layer 110 may have first and second surfaces opposite to each other. The second surface may be in contact with the buried insulating layer 101. A first mask pattern MP1 may be formed on the first surface of the active layer 110.

The first mask pattern MP1 may have line-shaped opening portions extending in the first direction D1. The first mask pattern MP1 may include a buffer layer B10, a first mask layer M10, a second mask layer M20, and a third mask layer M30, which are sequentially stacked. Herein, the third mask layer M30 may include or may be formed of a material having etching selectivity with respect to the second mask layer M20. The first mask layer M10 may include or may be formed of a material having etching selectivity with respect to the buffer layer B10 and the second mask layer M20. In some embodiments, the buffer layer B10 and the second mask layer M20 may include or may be formed of silicon oxide, and the first and third mask layers M10 and M30 may include or may be formed of silicon nitride.

Thereafter, the active layer 110 may be anisotropically etched by using the first mask pattern MP1 as an etching mask. Accordingly, first trenches T1 extending in the first direction D1 may be formed in the active layer 110. The first trenches T1 may expose the buried insulating layer 101 therethrough and may be separated by a certain distance from each other in the second direction D2.

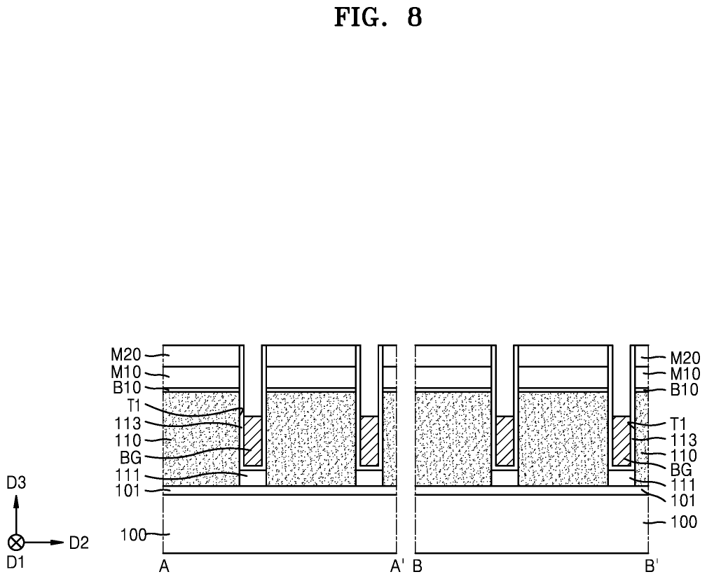

Referring to FIG. 8, first insulating patterns 111 respectively filling lower portions of the first trenches T1 may be formed.

The first insulating patterns 111 may be formed by forming an insulating material to fill the first trenches T1 and then etching the insulating material. Each first insulating pattern 111 may expose a portion of side walls of a corresponding first trench T1.

After forming the first insulating patterns 111, back-gate insulating patterns 113 and back-gate electrodes BG may be formed inside the first trenches T1, respectively. Particularly, after forming the first insulating patterns 111, a gate insulating layer conformally covering inner walls of the first trenches T1 may be formed, and a gate conductive layer may be formed to fill the first trenches T1 having the gate insulating layer formed thereon.

Thereafter, the back-gate electrodes BG may be formed inside the first trenches T1, respectively, by etching the gate conductive layer. While forming the back-gate electrodes BG, the third mask layer M30 may be removed.

In some embodiments, before forming the back-gate insulating patterns 113, the active layer 110 exposed through the inner walls of the first trenches T1 may be doped with impurities by performing a GPD or PLAD process.

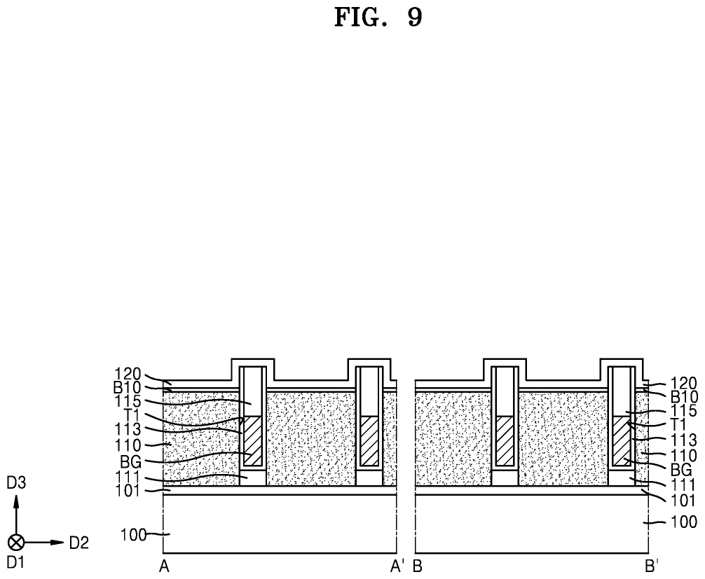

Referring to FIG. 9, back-gate capping patterns 115 may be formed inside the first trenches T1 having the back-gate electrodes BG formed therein, respectively.

The back-gate capping patterns 115 may be formed by forming an insulating layer to fill the first trenches T1 having the back-gate electrodes BG formed therein and then planarizing the insulating layer to expose an upper surface of the first mask layer M10. When the back-gate capping patterns 115 include or are formed of the same material as the second mask layer M20, the second mask layer M20 may be removed by a planarization process for forming the back-gate capping patterns 115.

Before forming the back-gate capping patterns 115, the active layer 110 may be doped with impurities through the first trenches T1 having the back-gate electrodes BG formed therein, by performing a GPD or PLAD process.

After forming the back-gate capping patterns 115, the first mask layer M10 may be removed so that the back-gate capping patterns 115 protrude upward from an upper surface of the buffer layer B10.

Thereafter, a spacer layer 120 covering the upper surface of the buffer layer B10, side walls of the back-gate insulating patterns 113, and upper surfaces of the back-gate capping patterns 115 with a uniform thickness may be formed. A width of each of active patterns of VCTs may be determined depending on the thickness of the spacer layer 120.

The spacer layer 120 may include or may be formed of an insulating material. The spacer layer 120 may include or may be formed of, for example, silicon oxide, silicon oxynitride, silicon nitride, SiC, or a combination thereof.

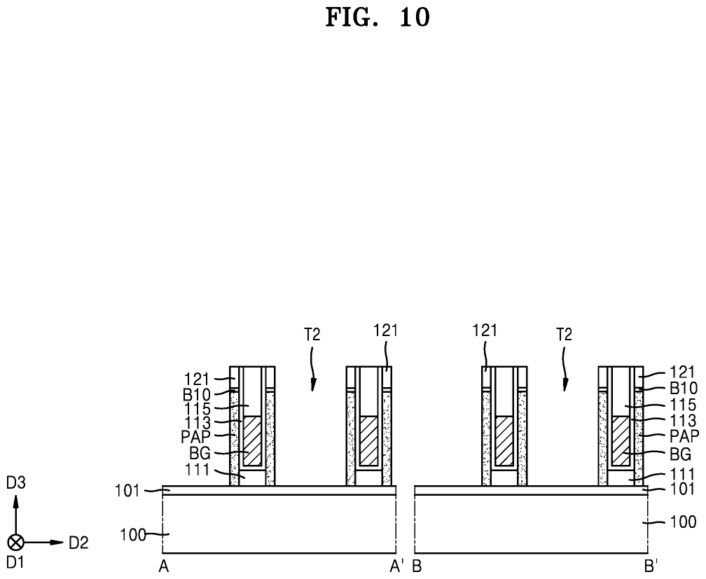

Referring to FIG. 10, an anisotropic etching process may be performed on the spacer layer 120 to form a pair of spacers 121 on side walls of each back-gate insulating pattern 113.

Thereafter, an anisotropic etching process on the active layer 110 may be performed by using the spacers 121 as an etching mask. Accordingly, a pair of preliminary active patterns PAP separated from each other may be formed at opposite sides of each back-gate insulating pattern 113.

By forming the preliminary active patterns PAP, the buried insulating layer 101 may be exposed. The preliminary active patterns PAP may have a line shape extending in the first direction D1 to be parallel to the back-gate electrode BG, and a second trench T2 may be formed between preliminary active patterns PAP adjacent to each other in the second direction D2.

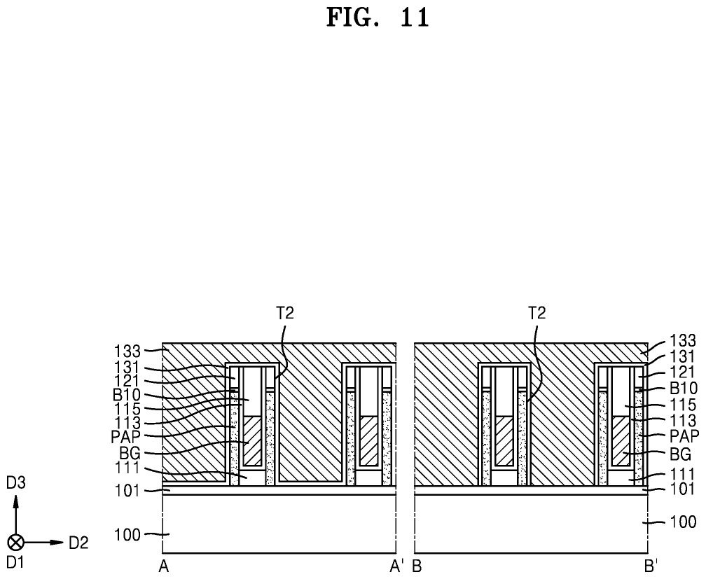

Referring to FIG. 11, a first etching stop layer 131 conformally covering an inner wall of the second trench T2 may be formed, and a first sacrificial layer 133 filling the second trench T2 having the first etching stop layer 131 formed thereon may be formed.

The first etching stop layer 131 may be formed of an insulating material, e.g., silicon oxide. The first sacrificial layer 133 may fill the second trench T2 and have a substantially flat upper surface. The first sacrificial layer 133 may be formed of an insulating material having etching selectivity with respect to the first etching stop layer 131. In some embodiment, the first sacrificial layer 133 may include or may be formed of any one of a silico oxide layer formed using a spin on glass (SOG) technique and an insulating material.

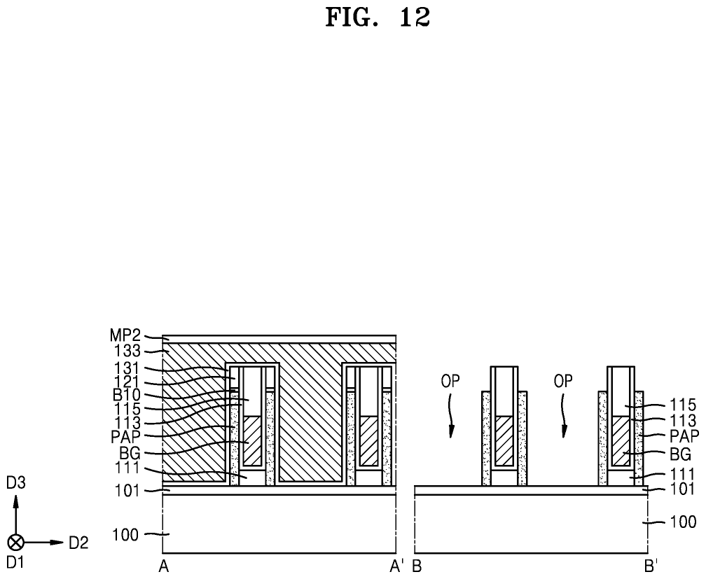

Referring to FIG. 12, a second mask pattern MP2 may be formed on the first sacrificial layer 133.

The second mask pattern MP2 may be formed of a material having etching selectivity with respect to the first sacrificial layer 133 and have a line shape extending in the second direction D2. In other embodiments, the second mask pattern MP2 may have a line shape extending in a diagonal direction with respect to the first and second directions D1 and D2.

Thereafter, openings OP exposing therethrough portions of the preliminary active patterns PAP may be formed by using the second mask pattern MP2 as an etching mask to sequentially etch the first sacrificial layer 133 and the first etching stop layer 131. The openings OP may expose an upper surface of the buried insulating layer 101.

During an etching process on the first sacrificial layer 133 and the first etching stop layer 131, the spacers 121 exposed through the second mask pattern MP2 may be removed.

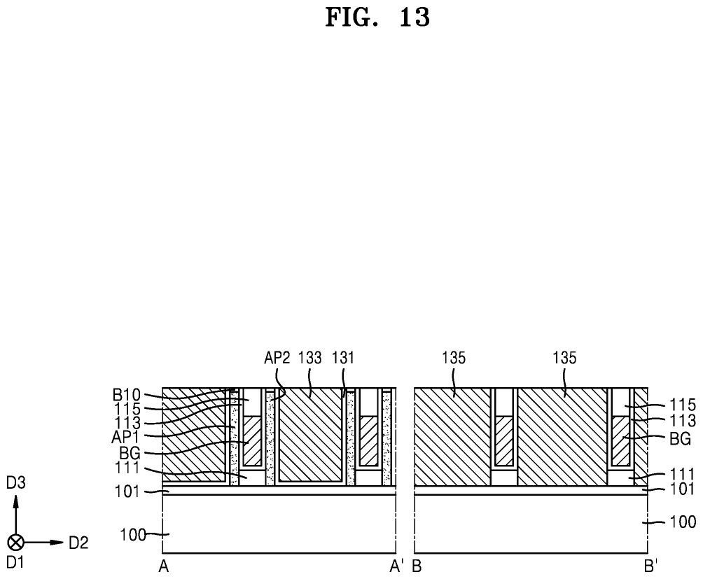

Referring to FIG. 13, the first and second active patterns AP1 and AP2 may be formed at opposite sides of the back-gate insulating patterns 113 by anisotropically etching the preliminary active patterns PAP exposed through the openings OP (see FIG. 12).

The first active patterns AP1 may be respectively formed on first side walls of the back-gate electrodes BG to be separated from each other in the first direction D1, and the second active patterns AP2 may be respectively formed on second side walls of the back-gate electrodes BG to be separated from each other in the first direction D1. In other embodiments, when the second mask pattern MP2 extends in the diagonal direction, the first and second active patterns AP1 and AP2 may be arranged to face each other in the diagonal direction.

After forming the first and second active patterns AP1 and AP2, a second sacrificial layer 135 may fill the openings OP (see FIG. 12). The second sacrificial layer 135 may be formed of an insulating material having etching selectivity with respect to the first etching stop layer 131. In some embodiments, the second sacrificial layer 135 may be formed of the same material as the first sacrificial layer 133.

After forming the second sacrificial layer 135, the second mask pattern MP2 may be removed, and a planarization process may be performed on the first and second sacrificial layers 133 and 135 to expose the upper surfaces of the back-gate capping patterns 115.

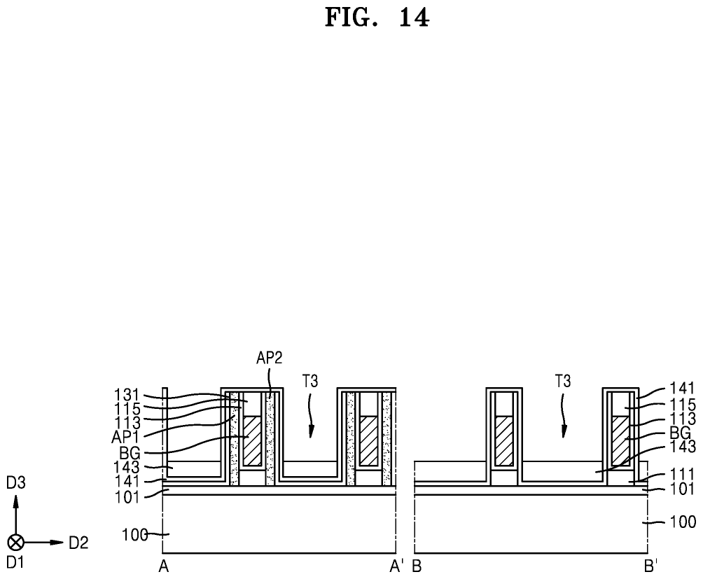

Referring to FIG. 14, the first and second sacrificial layers 133 and 135 (see FIG. 13) may be removed, and the first etching stop layer 131 may be exposed between first and second active patterns AP1 and AP2 facing each other in the second direction D2.

Thereafter, a second etching stop layer 141 may formed with a uniform thickness in a third trench T3 having the first etching stop layer 131 formed thereon. Particularly, the second etching stop layer 141 may be formed on portions of the first etching stop layer 131, the back-gate insulating patterns 113, the back-gate capping patterns 115, and the buried insulating layer 101. The second etching stop layer 141 may be formed of a material having etching selectivity with respect to the first etching stop layer 131.

The second insulating pattern 143 filling a portion of the third trench T3 having the second etching stop layer 141 formed therein may be formed.

The second insulating pattern 143 may be formed by using the SOG technique to form an insulating layer filling the third trench T3, and then etching the insulating layer. The second insulating pattern 143 may include or may be formed of fluoride silicate glass (FSG), SOG, tonen silazene (TOSZ), or the like.

A level of an upper surface of the second insulating pattern 143 may vary depending on an etching process. In some embodiments, the upper surface of the second insulating pattern 143 may be positioned at a higher level than a lower surface of the back-gate electrode BG. Alternatively, the upper surface of the second insulating pattern 143 may be positioned at a lower level than the lower surface of the back-gate electrode BG.

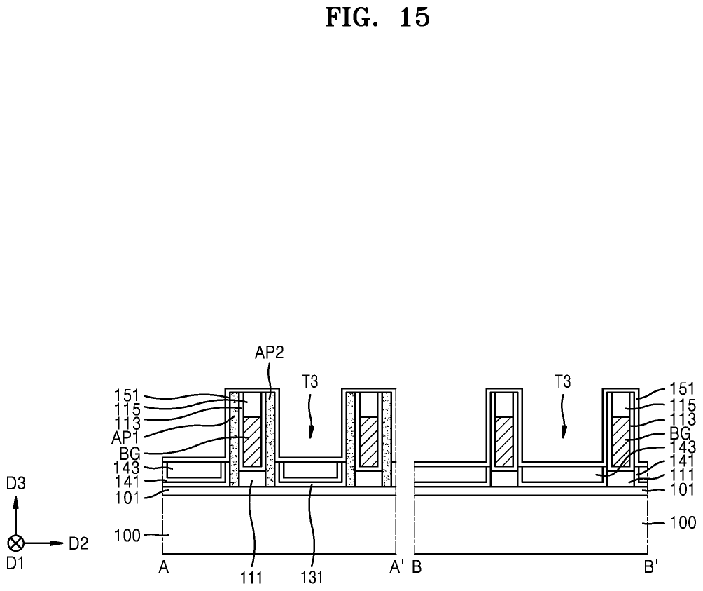

Referring to FIG. 15, the first and second active patterns AP1 and AP2 may be exposed in the third trench T3 by etching the first and second etching stop layers 131 and 141 exposed by the second insulating pattern 143.

Thereafter, a gate insulating layer 151 conformally covering side walls of the first and second active patterns AP1 and AP2, the upper surfaces of the back-gate capping patterns 115, and the upper surface of the second insulating pattern 143 may be formed.

The gate insulating layer 151 may be formed using any one of physical vapor deposition (PVD), thermal CVD, low pressure CVD (LP-CVD), plasma enhanced CVD (PE-CVD), and atomic layer deposition (ALD).

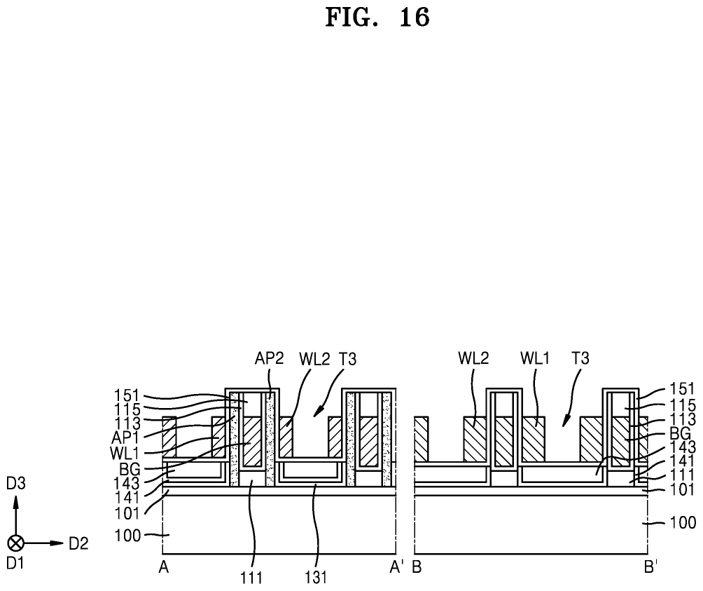

Referring to FIG. 16, after forming the gate insulating layer 151, the first and second word lines WL1 and WL2 may be formed on the side walls of the first and second active patterns AP1 and AP2.

The forming of the first and second word lines WL1 and WL2 may include forming a gate conductive layer conformally covering the gate insulating layer 151, and then performing an anisotropic etching process on the gate conductive layer. Herein, a thickness of the gate conductive layer may be less than a half of a width of the third trench T3. The gate conductive layer may define a gap region in the third trench T3 and may be formed on the gate insulating layer 151.

During a time when the anisotropic etching process is performed on the gate conductive layer, the gate insulating layer 151 may be used as an etching stop layer, or the gate insulating layer 151 may be over-etched so that the second insulating pattern 143 is exposed. According to the anisotropic etching process that is performed on the gate conductive layer, the first and second word lines WL1 and WL2 may have various shapes.

Upper surfaces of the first and second word lines WL1 and WL2 may be positioned at a lower level than upper surfaces of the first and second active patterns AP1 and AP2.

After forming the first and second word lines WL1 and WL2, a GPD or PLAD process may be performed to dope the active layer 110 with impurities through the gate insulating layer 151 exposed by the first and second word lines WL1 and WL2.

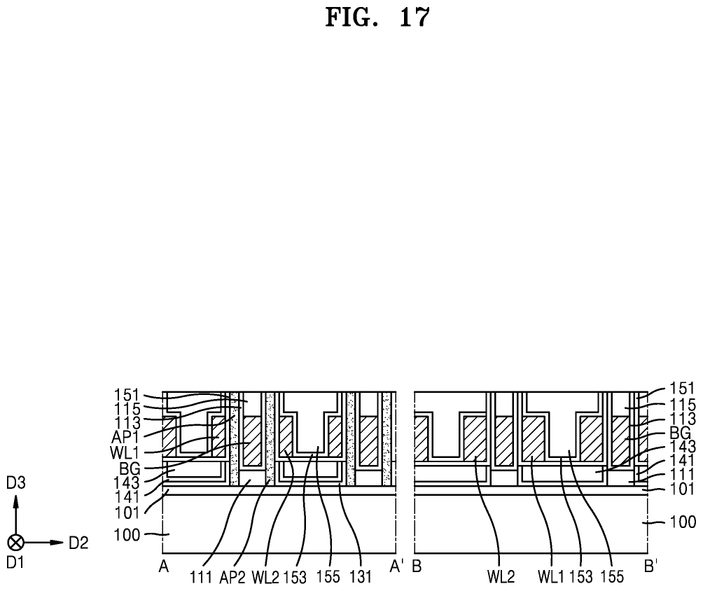

Referring to FIG. 17, the first capping layer 153 and a third insulating layer 155 may be sequentially formed in the third trench T3 (see FIG. 16) having the first and second word lines WL1 and WL2 formed therein.

Particularly, the first capping layer 153 may be conformally formed above the whole surface of the first substrate 100. The first capping layer 153 may include or may be formed of, for example, silicon nitride, silicon oxynitride, SiC, or a combination thereof. The first capping layer 153 may cover the surfaces of the first and second word lines WL1 and WL2.

Thereafter, the third insulating layer 155 may be formed to fill the third trench T3 (see FIG. 16) having the first capping layer 153 formed therein. Herein, the third insulating layer 155 may include or may be formed of an insulating material that is different from that of the first capping layer 153.

Thereafter, a planarization process may be performed on the third insulating layer 155 and the first capping layer 153 to expose the upper surfaces of the back-gate capping patterns 115. Accordingly, the upper surfaces of the first and second active patterns AP1 and AP2 may be exposed.

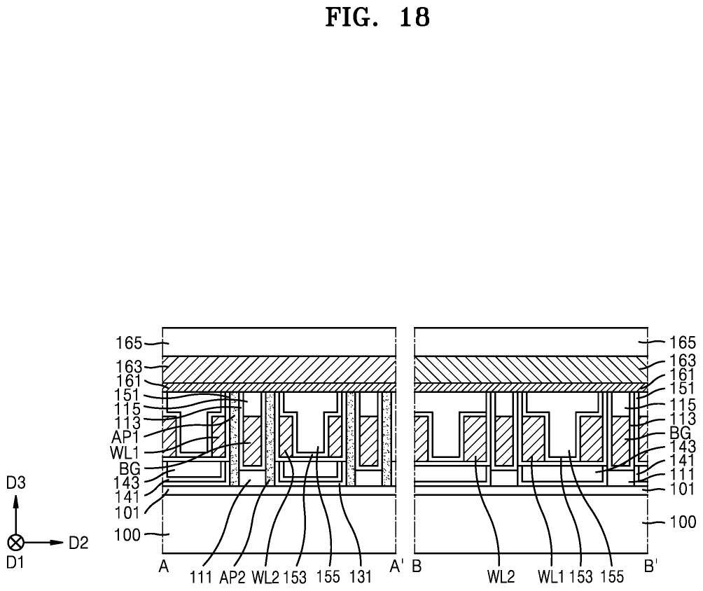

Referring to FIG. 18, a polysilicon layer 161 may be formed above the whole surface of the first substrate 100.

The polysilicon layer 161 may be in contact with the upper surfaces of the first and second active patterns AP1 and AP2. Thereafter, a metal layer 163 and a hardmask layer 165 may be sequentially formed on the polysilicon layer 161.

The metal layer 163 may be formed of conductive metal nitride or a metal (e.g., W, Ti, or Ta). The hardmask layer 165 may be formed of an insulating material, such as silicon nitride and silicon oxynitride.

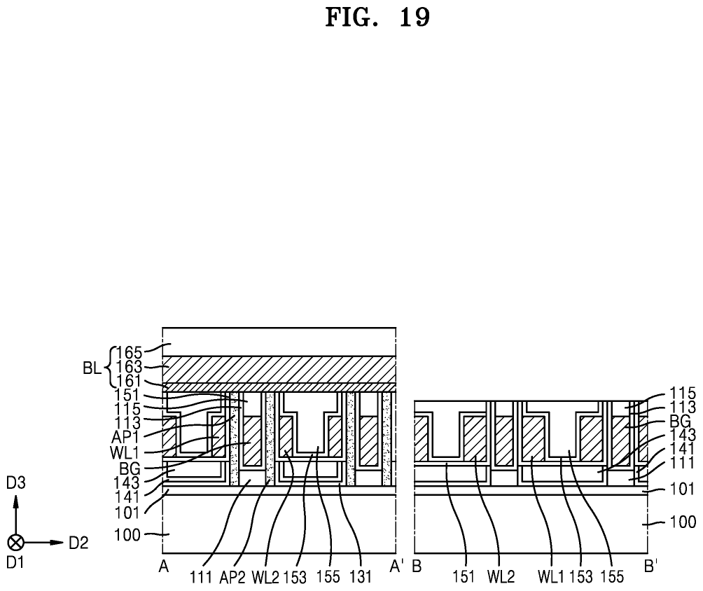

Referring to FIG. 19, a mask pattern (not shown) having a line shape extending in the second direction D2 may be formed on the hardmask layer 165 and may be used to sequentially and anisotropically etch the hardmask layer 165, the metal layer 163, and the polysilicon layer 161.

Accordingly, the bit lines BL separated from each other in the first direction D1 and extending in the second direction D2 may be formed. When forming the bit lines BL, portions of the back-gate capping patterns 115 may be etched together.

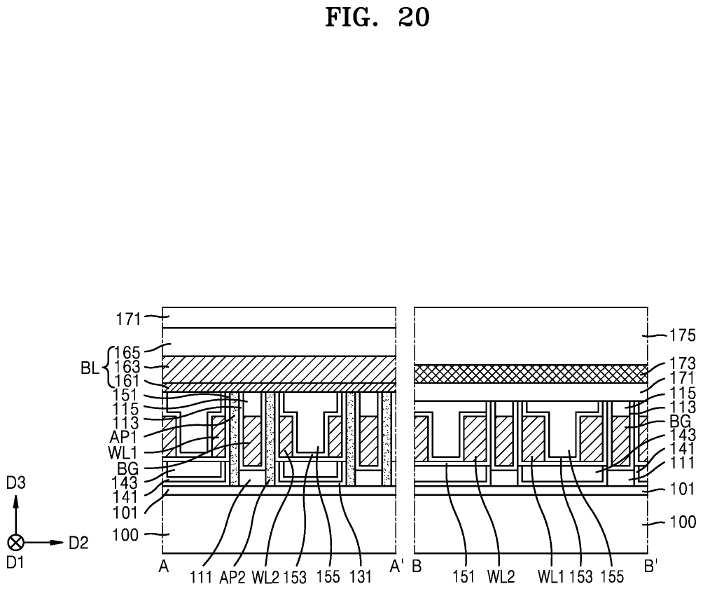

Referring to FIG. 20, after forming the bit lines BL, a third insulating layer 171 defining gap regions between the bit lines BL may be formed.

The third insulating layer 171 may have a substantially uniform thickness and may be formed above the whole surface of the first substrate 100. A thickness of the third insulating layer 171 may be less than a half of a gap between bit lines BL adjacent to each other. By forming the third insulating layer 171, the gap regions may be defined between the bit lines BL by the third insulating layer 171. The gap regions may extend in the second direction D2 to be parallel to the bit lines BL.

After forming the third insulating layer 171, shield lines formed of a conductive material or the gap structures 173 including an insulating material may be formed in the gap regions of the third insulating layer 171. The gap structures 173 may be formed between the bit lines BL, respectively. In some embodiments, the forming of the gap structures 173 may include forming a shield layer on the third insulating layer 171 to fill the gap regions and forming a recess in an upper surface of the shield layer.

The upper surfaces of the gap structures 173 may be positioned at a lower level than the upper surfaces of the bit lines BL. The gap structures 173 may include or may be formed of metal, e.g., W, Ti, Ni, or cobalt (Co). In other embodiments, the gap structures 173 may include or may be formed of a conductive material including carbon, such as graphene. The gap structures 173 may include or may be formed of a low-k dielectric material having a lower dielectric constant than that of the third insulating layer 171.

After forming the gap structures 173, capping insulating patterns 175 may be formed on the gap structures 173, respectively. The forming of the capping insulating patterns 175 may include forming a capping insulating layer filling the gap regions in which the gap structures 173 are respectively formed, and performing a planarization process on the capping insulating layer and the third insulating layer 171 to expose the upper surfaces of the bit lines BL, i.e., an upper surface of the hardmask layer 165.

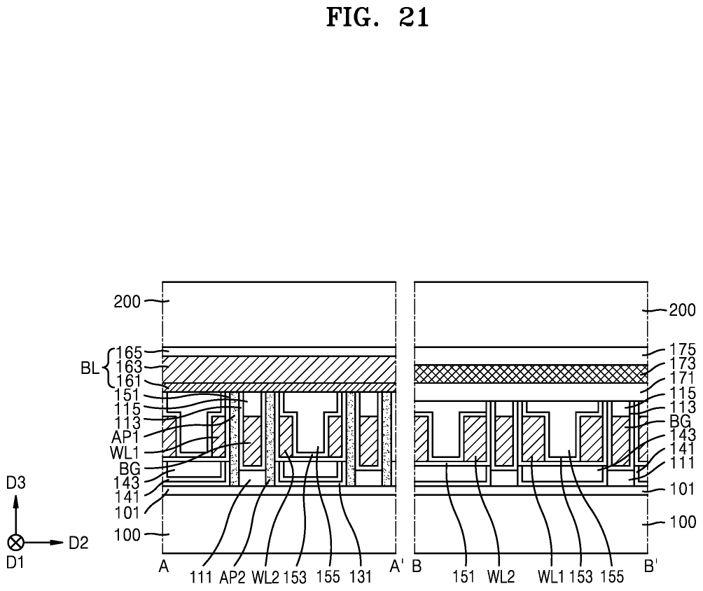

Referring to FIG. 21 the first substrate 100 on which the back-gate electrodes BG, the first and second word lines WL1 and WL2, the first and second active patterns AP1 and AP2, and the bit lines BL are formed may be bonded to the substrate 200.

The substrate 200 may be bonded to the upper surfaces of the bit lines BL, i.e., the upper surface of the hardmask layer 165 and upper surfaces of the capping insulating patterns 175. The substrate 200 may include or may be formed of, for example, monocrystalline Si, glass, or quartz.

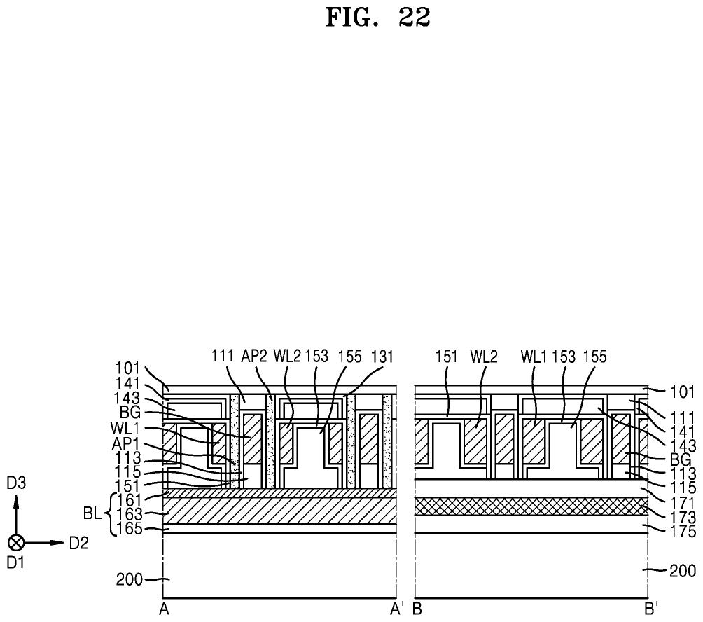

Referring to FIG. 22, after bonding the substrate 200, a rear lapping process of removing the first substrate 100 (see FIG. 21) may be performed.

The removing of the first substrate 100 (see FIG. 21) may include exposing the buried insulating layer 101 by sequentially performing a grinding process and a wet etching process.

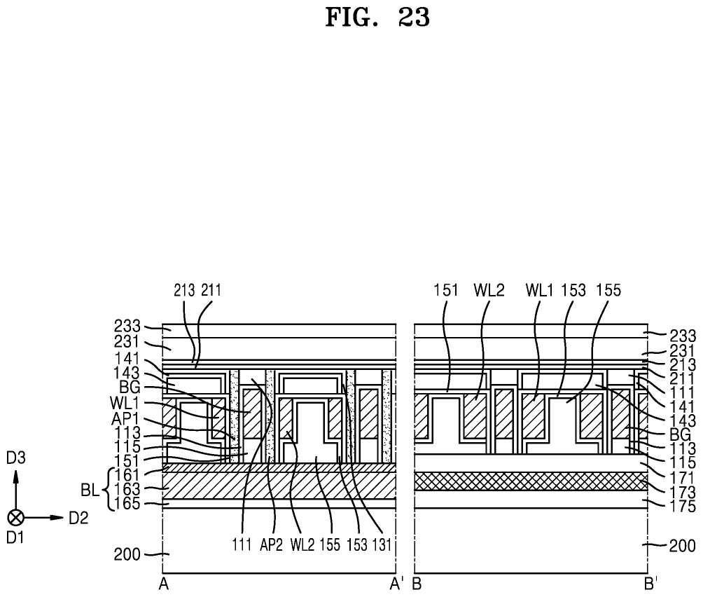

Referring to FIG. 23, the buried insulating layer 101 may be removed to expose the first and second active patterns AP1 and AP2, the first insulating patterns 111, and the back-gate insulating patterns 113.

Thereafter, third and fourth etching stop layers 211 and 213 may be sequentially formed. The third etching stop layer 211 may be formed of silicon oxide and may be formed on the first and second active patterns AP1 and AP2, the first insulating patterns 111, and the back-gate insulating patterns 113. The fourth etching stop layer 213 may be formed of a material, e.g., silicon nitride, having etching selectivity with respect to the third etching stop layer 211.

The interlayer insulating layer 231 and an etching stop layer 233 may be formed. The etching stop layer 233 may be formed of an insulating material having etching selectivity with respect to the interlayer insulating layer 231.

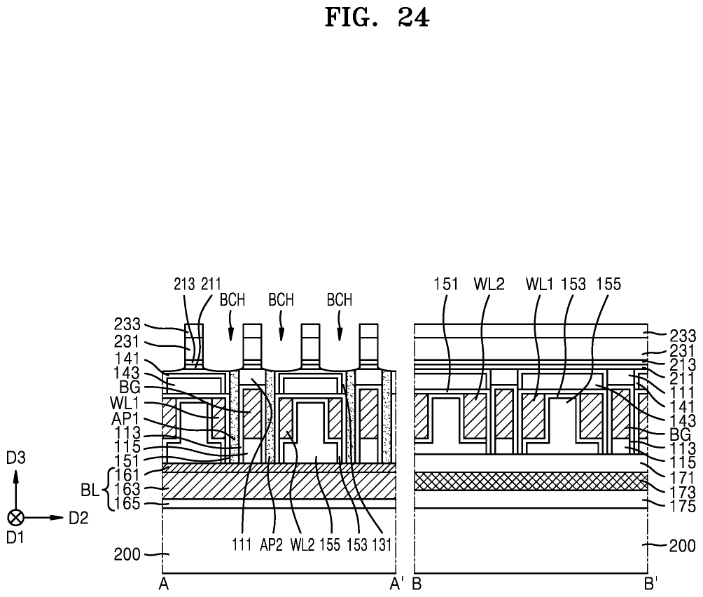

Referring to FIG. 24, contact holes BCH passing through the interlayer insulating layer 231 and the etching stop layer 233 and respectively exposing the first and second active patterns AP1 and AP2 may be formed.

The contact holes BCH may be formed to expose the upper surfaces of the first and second active patterns AP1 and AP2, respectively. The contact holes BCH may be separated from each other in the first and second directions D1 and D2. In addition, the contact holes BCH may expose upper surfaces of the third and fourth etching stop layers 211 and 213 adjacent to the first and second active patterns AP1 and AP2, and side surfaces of the interlayer insulating layer 231 and the etching stop layer 233.

The contact holes BCH may have a shape, such as a circular shape, an oval shape, a polygonal shape, and a rounded polygonal shape, in a top view. In some embodiments, the contact holes BCH may be arranged in a lattice shape in a top view. In other embodiments, the contact holes BCH may be arranged in a honeycomb shape in a top view.

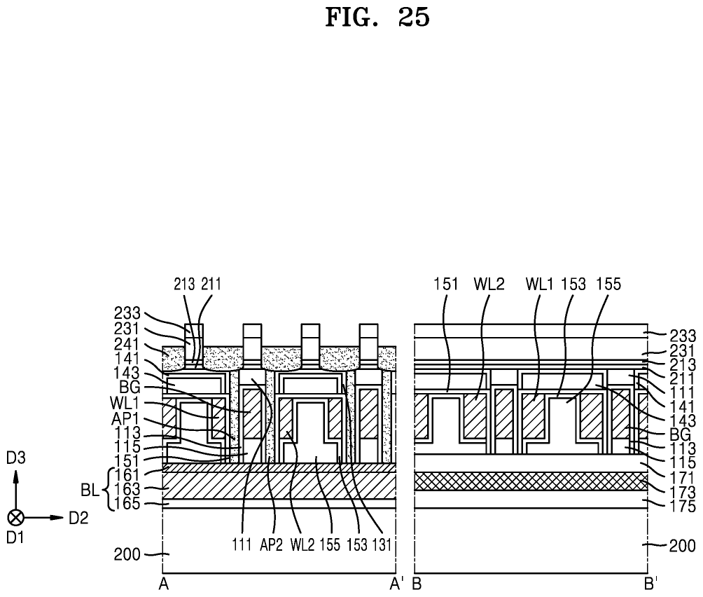

Referring to FIG. 25, the epitaxial growth layer 241 may be formed to fill a portion of each of the contact holes BCH (see FIG. 24).

The epitaxial growth layer 241 may be formed from each of the upper surfaces of the first and second active patterns AP1 and AP2 by using an SEG process. The epitaxial growth layer 241 may be formed in an undoped state or a state doped at a low concentration. In addition, the epitaxial growth layer 241 may include or may be formed of a monocrystalline Si epitaxial growth layer or a SiGe epitaxial growth layer but is not limited thereto.

In addition, a process of effectively controlling thickness distribution of the epitaxial growth layer 241 by forming a sacrificial layer (not shown) on the epitaxial growth layer 241 and then removing the sacrificial layer may be further included.

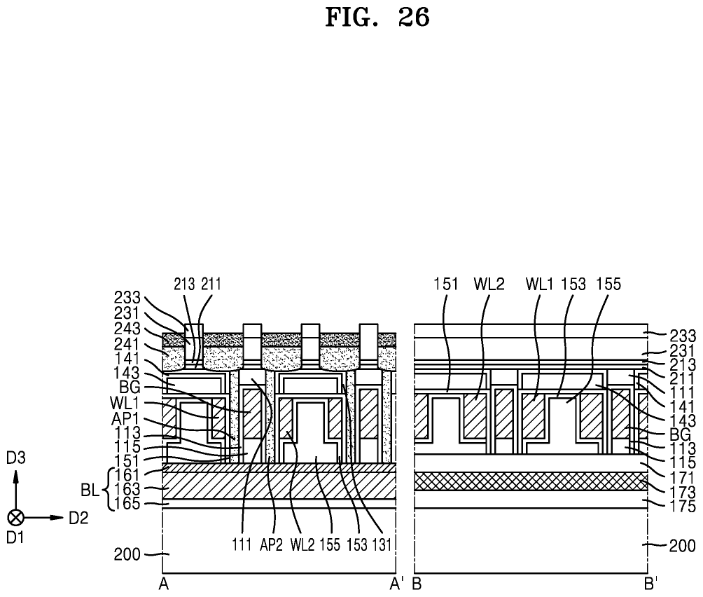

Referring to FIG. 26, the doped polysilicon layer 243 may be formed to partially fill each of the contact holes BCH (see FIG. 24).

The doped polysilicon layer 243 may be provided by forming, on the epitaxial growth layer 241, polysilicon doped with an n-type dopant or a p-type dopant at a high concentration.

A doping concentration of dopants in the doped polysilicon layer 243 may be sufficiently high so that some of the dopants included in the doped polysilicon layer 243 move to the epitaxial growth layer 241 and dope the epitaxial growth layer 241.

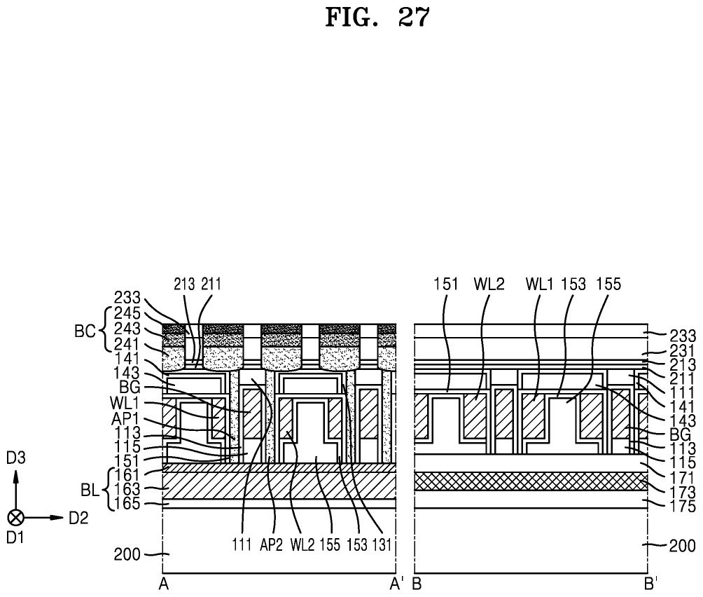

Referring to FIG. 27, the silicide layer 245 may be formed to completely fill the other portion of each of the contact holes BCH (see FIG. 24).

The silicide layer 245 may include or may be formed of metal silicide, e.g., CoSi, NiSi, or TiSi.

The silicide layer 245 may be formed by forming, on the doped polysilicon layer 243, a metal layer filling each of the contact holes BCH (see FIG. 24), reacting the metal layer react with the doped polysilicon layer 243 to form the silicide layer 245, and then removing a remaining portion of the metal layer, which has not reacted.

By performing an annealing process, some of highly concentrated dopants included in the doped polysilicon layer 243 may move to the epitaxial growth layer 241. Therefore, the epitaxial growth layer 241 may have a doping concentration gradually decreasing away from a junction interface with the doped polysilicon layer 243. Accordingly, the epitaxial growth layer 241 may have a certain junction depth.

Then, the contact patterns BC each including the epitaxial growth layer 241 gradually doped, the doped polysilicon layer 243 doped at a high concentration, and the silicide layer 245 may be respectively formed in the contact holes BCH (see FIG. 24).

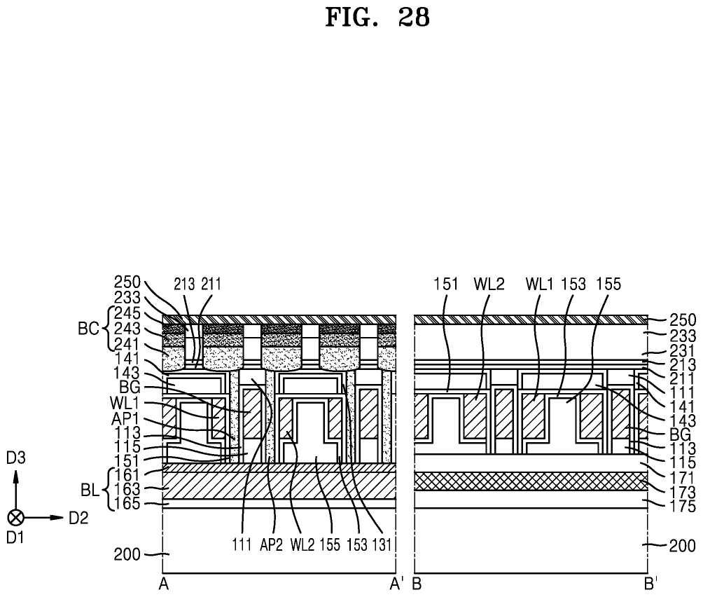

Referring to FIG. 28, a conductive layer 250 may be formed to cover all over upper surfaces of the contact patterns BC and an upper surface of the etching stop layer 233.

The conductive layer 250 may include or may be formed of a material forming the landing pads LP described below. For example, the conductive layer 250 may include or may be formed of metal, such as Ti, Ta, and W.

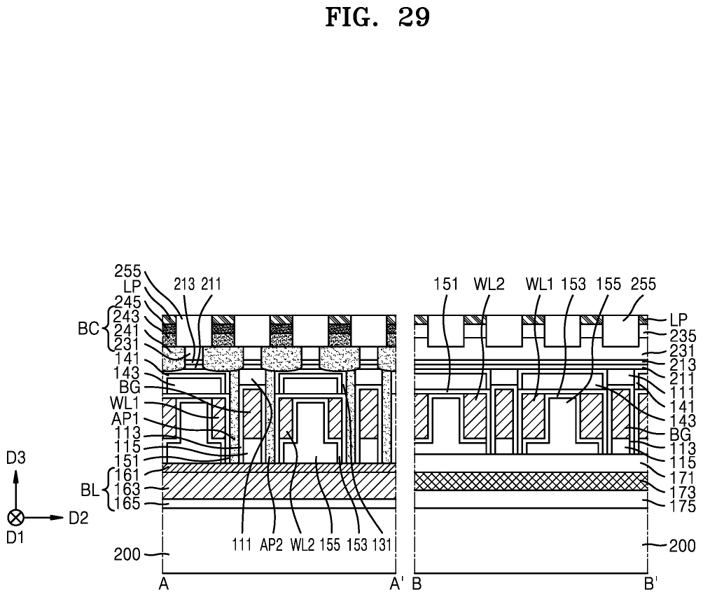

Referring to FIG. 29, the landing pads LP respectively connected to the contact patterns BC may be formed by patterning the conductive layer 250 (see FIG. 28).

The forming of the landing pads LP may include forming recess regions by using mask patterns to anisotropically etch the etching stop layer 233 (see FIG. 28) between the conductive layer 250 (see FIG. 28) and the contact patterns BC, and the interlayer insulating layer 231, and forming the isolation insulating patterns 255 by burying an insulating material in the recess regions, respectively.

Herein, during a time when the recess regions are formed, portions of the contact patterns BC may be etched. The upper surfaces of the isolation insulating patterns 255 may be substantially coplanar with the upper surfaces of the landing pads LP.

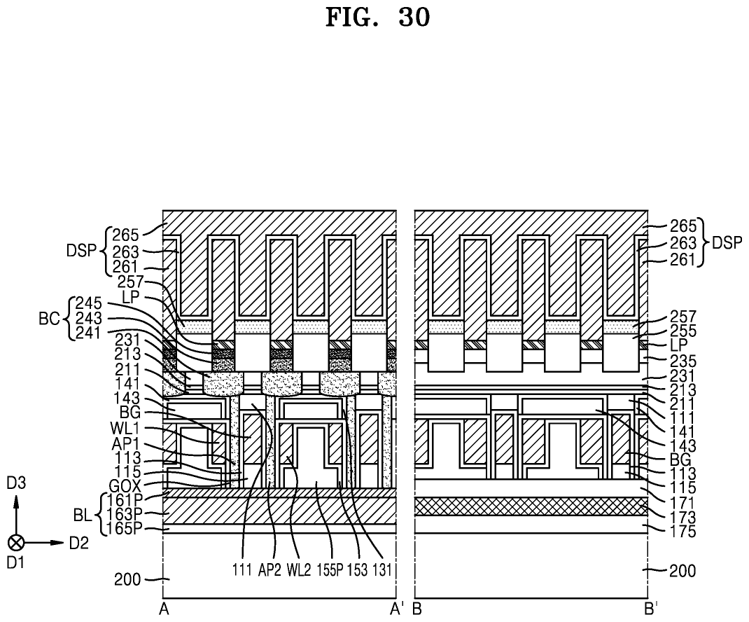

Referring to FIG. 30, capacitors of the data storage patterns DSP may be formed on the landing pads LP, respectively.

Particularly, the storage electrodes 261 may be formed on the landing pads LP, respectively, and the capacitor dielectric layer 263 conformally covering the surfaces of the storage electrodes 261 may be formed. Thereafter, the plate electrode 265 may be formed on the capacitor dielectric layer 263.

Referring back to FIG. 3, the semiconductor device 10 according to the inventive concept may be manufactured by forming the upper insulating layer 270 on the data storage patterns DSP and forming the cell contact plugs PLG connected to the plate electrode 265 by passing through the upper insulating layer 270.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a first bit line extending on the substrate in a first direction;
first and second active patterns on the first bit line;
a back-gate electrode between the first and second active patterns and extending across the first bit line in a second direction that is perpendicular to the first direction;
a first word line extending in the second direction, wherein the first active pattern is disposed between the first word line and the back-gate electrode;
a second word line extending in the second direction, wherein the second active pattern is disposed between the second word line and the back-gate electrode; and
a contact pattern connected to each of the first and second active patterns,
wherein the contact pattern includes an epitaxial growth layer, a doped polysilicon layer, and a silicide layer that are stacked on each other in a vertical direction perpendicular to an upper surface of the substrate.

2. The semiconductor device of claim 1,
wherein each of the first and second active patterns includes a monocrystalline semi conductor material,
wherein the epitaxial growth layer of the contact pattern contacts the first and second active patterns, and
wherein the epitaxial growth layer has a doping concentration gradually varying in the vertical direction.

3. The semiconductor device of claim 2,
wherein the doping concentration of the epitaxial growth layer gradually decreases away from the doped polysilicon layer.

4. The semiconductor device of claim 3,
wherein a lower region of the epitaxial growth layer contacts each of the first and second active patterns, and
wherein the lower region of the epitaxial growth layer is an undoped region.

5. The semiconductor device of claim 3,
wherein a type of a dopant in the epitaxial growth layer is the same as a type of a dopant in the doped polysilicon layer.

6. The semiconductor device of claim 5,
wherein the epitaxial growth layer is silicon (Si) epitaxial growth layer, and
wherein the dopant of the epitaxial growth layer is an n-type dopant.

7. The semiconductor device of claim 1,
wherein each of the first and second active patterns comprises:
a source/drain region adjacent to the contact pattern; and
a channel region adjacent to the first and second word lines, and
wherein a doping concentration of the source/drain region is greater than a doping concentration of the channel region.

8. The semiconductor device of claim 1, further comprising:
a data storage pattern connected to the contact pattern; and
a landing pad disposed between the contact pattern and the data storage pattern.

9. The semiconductor device of claim 8,
wherein the landing pad contacts the silicide layer of the contact pattern.

10. The semiconductor device of claim 1, further comprising:
a second bit line adjacent to the first bit line;
a gap structure disposed in a space between the first and second bit lines; and
an insulating pattern between the gap structure and the first bit line,
wherein the gap structure includes a conductive material.

11. A semiconductor device comprising:
a substrate;
a bit line extending on the substrate in a first direction;
first and second active patterns on the bit line;
a back-gate electrode between the first and second active patterns and extending across the bit line in a second direction that is perpendicular to the first direction;
a first word line extending in the second direction at a first side of the first active pattern;
a second word line extending in the second direction at a second side of the second active pattern; and
a contact pattern connected to each of the first and second active patterns,
wherein the contact pattern comprises an undoped epitaxial growth layer, a doped epitaxial growth layer, and a silicide layer that are stacked on each other in a vertical direction perpendicular to an upper surface of the substrate.

12. The semiconductor device of claim 11,
wherein a doping concentration of the doped epitaxial growth layer gradually increases away from the undoped epitaxial growth layer.

13. The semiconductor device of claim 11,
wherein each of the first and second active patterns comprises:
a source/drain region adjacent to the contact pattern; and
a channel region adjacent to the first and second word lines, and
wherein a doping concentration of the source/drain region is greater than a doping concentration of the channel region.

14. The semiconductor device of claim 13,
wherein a self-aligned junction is formed between the contact pattern and each of the first and second active patterns.

15. The semiconductor device of claim 14,
wherein the self-aligned junction has a certain junction depth.

16. A semiconductor device comprising:
a substrate;
a first bit line extending on the substrate in a first direction;
a second bit line adjacent to the first bit line;
a gap structure disposed in a space between the first and second bit lines and extending in the first direction;
first and second active patterns alternately arranged on the first bit line in the first direction;
a back-gate electrode between the first and second active patterns and extending across the first bit line in a second direction that is perpendicular to the first direction;
a first word line neighboring to the first active pattern and extending in the second direction;
a second word line neighboring to the second active pattern and extending in the second direction;
a gate insulating pattern between the first and second active patterns and the first and second word lines;
a back-gate insulating pattern between the back-gate electrode and each of the first and second active patterns;
a contact pattern connected to each of the first and second active patterns;
a landing pad on the contact pattern; and
a data storage pattern connected to the landing pad,
wherein the contact pattern comprises:
an undoped epitaxial growth layer;
a doped epitaxial growth layer on the undoped epitaxial growth layer and having a gradually increasing doping concentration;
a doped polysilicon layer on the doped epitaxial growth layer and doped at a higher concentration than that of the doped epitaxial growth layer; and
a metal silicide layer on the doped polysilicon layer.

17. The semiconductor device of claim 16,
wherein a type of a dopant in the doped epitaxial growth layer is the same as a type of a dopant in the doped polysilicon layer, and
wherein the doping concentration of the doped epitaxial growth layer gradually decreases away from the doped polysilicon layer.

18. The semiconductor device of claim 17,
wherein the doping concentration of the doped epitaxial growth layer is about 3×10²⁰/cm³ near the doped polysilicon layer, and
wherein the doping concentration of the doped epitaxial growth layer is about 2.5×10¹⁹/cm³ near the undoped epitaxial growth layer.

19. The semiconductor device of claim 16,
wherein each of the first and second active patterns includes a monocrystalline semiconductor material,
wherein each of the first and second active patterns comprises:
a source/drain region adjacent to the contact pattern; and
a channel region adjacent to the first and second word lines, and
wherein a doping concentration of the source/drain region is greater than a doping concentration of the channel region.

20. The semiconductor device of claim 16,
wherein each of the undoped epitaxial growth layer and the doped epitaxial growth layer in the contact pattern is a silicon (Si) epitaxial growth layer, and
wherein the metal silicide layer in the contact pattern is a cobalt (Co) silicide layer.
